(19) United States
(12) Patent Application Publication
(10) Pub. No.: US 2023/0386965 A1
(43) Pub. Date: Nov. 30, 2023

(54) HEATSINK UNIT, IC SOCKET, METHOD FOR MANUFACTURING SEMICONDUCTOR PACKAGE, AND SEMICONDUCTOR PACKAGE

(71) Applicant: YAMAICHI ELECTRONICS CO., LTD., Tokyo (JP)

(72) Inventors: Koichi MIWA, Tokyo (JP); Hideki SAGANO, Tokyo (JP); Masaru SATO, Tokyo (JP)

(21) Appl. No.: 18/034,602

(22) PCT Filed: Oct. 7, 2021
(86) PCT No.: PCT/JP2021/037115

§ 371 Date: Apr. 28, 2023

(30) Foreign Application Priority Data
Oct. 28, 2020 (JP) 2020-180283

(51) Int. Cl. H01L 23/40

(52) U.S. Cl. CPC H01L 23/4006; H01L 2023/4087; H01L 2023/405; H01L 22/20

(57) ABSTRACT

The present invention provides a heat sink unit that has a small mounting area and high radiating efficiency without breaking or damaging the IC package. The heat sink unit includes a base, a heat sink, a unit base, a heat sink mount, a frame member, a first lever, and a second lever. When the frame member 6 reaches a confronting position, further rocking is restricted, the heat sink mount supported by the frame member moves downward, and the end surface of the heat sink supported by the heat sink mount comes into contact with the IC package.

### CROSS-REFERENCE TO RELATED APPLICATIONS AND PRIORITY

This patent application claims priority from PCT Patent Application No. PCT/JP2021/037115 filed Oct. 7, 2021 which claims priority to Japanese Patent Application No. 2020-180283 filed Oct. 28, 2020. Each of these patent applications are herein incorporated by reference in its/their entirety.

### TECHNICAL FIELD

The present invention relates to techniques for assisting the radiating of an IC package during burn-in test.

### BACKGROUND

In a burn-in test of an IC (integrated circuit) package such as a BGA (ball grid array) device, after the IC package to be tested is accommodated in an IC (integrated circuit) socket for electrical connection test, an electric signal is supplied to the IC package through contact pins of the IC socket from a wiring substrate on which the IC socket is supported and fixed, and various evaluations such as electrical characteristics, durability, and heat resistance are performed. During the burn-in test of the IC package, heat is generated by the power supply to the IC package, so an IC socket and an attachment-type heat sink unit surrounding it may be used together.

As a document disclosing a technique related to this type of heat sink unit, Patent Document 1 can be taken up. The attachment for socket disclosed in Patent Document 1 includes a base frame surrounding the sides of an IC socket, a top frame floatingly supported on the base frame by a coil spring, two arms pivotally supported by drive shafts on the left and right edge walls surrounding the IC socket in the top frame, and two heat sinks supported on the two arms. In this attachment for socket, when each pair of the arm and the heat sink is closed, the bottom of the base of the heat sink is in contact with the IC package in the IC socket, the heat of the IC package is transferred from the base to a cooling fin, and the heat is dissipated from the cooling fin. In addition, when each pair of the arm and the heat sink is opened, the IC socket in the opening portion of the base frame is exposed upward, and the IC package accommodated in the IC socket can be taken out.

### PRIOR ART REFERENCE

### Patent Document

Patent Document 1: Japanese Patent No. 5095964

### SUMMARY

### Problems to be Solved

However, the technique of Patent Document 1 has the following problems. In Patent Document 1, the action of the heat sink during the opening and closing operation in the attachment for socket carrying the heat sink was a motion along a trajectory on an arc, and the two heat sinks were operated in contact and non-contact by the operation of the arms. Therefore, when the heat sink came into contact with the IC package, the heat sink tilted and came into contact with the IC package from the end portion of the heat sink, causing damage such as scratches or chips to the IC package. In addition, if the operation speed in the process of closing the heat sink is fast, the heat sink might damage the IC package due to the impact when it is closed. In addition, since a plurality of heat sinks are installed, a plurality of structures for opening and closing the heat sinks are required, and the space occupied by the heat sink units is increased. In addition, since the heat sink is opened in two or more directions in the open state, the directions of access to the socket and the heat sink unit of the device for inserting and removing the IC package were limited to the upper surface and two directions or less.

The present invention has been made in view of such problems, and one of the objects is to provide a heat sink unit that has a small mounting area and high radiating efficiency without breaking or damaging the IC package.

### Means for Solving the Problem

In order to solve the above problems, a heat sink, which is a preferred aspect of the present invention, is a heat sink unit that dissipates heat of an IC (integrated circuit) package accommodated in an IC (integrated circuit) socket, and is characterized by including: a heat sink having a base and a plurality of radiating fins erected from the base; a unit base mounted on a substrate so as to surround the IC socket; a frame member that has a first opening and supports the heat sink so that a base of the heat sink passes through the first opening, wherein the frame member is supported by the unit base so as to be rockable between a confronting position and an open position tilting with respect to the confronting position, and the confronting position is where an end surface of the base on a side opposite to the radiating fins side and the IC package confront each other at an interval; and a first lever in which an intermediate portion between one end and the other end of the first lever is pivotally supported at a first pivoting point of the frame member, when the frame member reaches the confronting position, further rocking is restricted, the heat sink supported by the frame member moves downward, and the end surface of the heat sink comes into contact with the IC package.

In this aspect, a heat sink mount that has a second opening and supports the heat sink so that the base of the heat sink passes through the second opening may be included, and the frame member may support the heat sink and the heat sink mount.

Further, when the frame member reaches the confronting position, the further rocking may be restricted, and the heat sink mount and the heat sink supported thereon may move downward.

Further, one end side portion of the first lever may be in contact with and separated from the heat sink mount.

Further, a second lever may be included, wherein an intermediate portion between one end and the other end of the second lever is pivotally supported at the first pivoting point on the frame member, and one end side portion of the second lever is pivotally supported at a second pivoting point on the frame member that is separated from the first pivoting point.

Further, a driving mechanism may be included, in which a force is generated to lift upward the other end side portion of the second lever and the other end side portion of the first lever when the frame member is rocked from the open position toward the confronting position.

Further, a cover combined with the unit base; and a first coil spring that is sandwiched between the unit base and the cover to form the driving mechanism may be included, wherein a proximal end side portion of the second lever and a proximal end side portion of the first lever may be pivotally supported at a third pivoting point on the side plate of the cover.

Further, when the frame member is at the open position, the proximal end side portion of the first lever is lowered in conjunction with the pushing-down operation of the cover, so an elastic restoring force of the first coil spring may be released when the first pivoting point passes a position directly above the third pivoting point by rotation of the first lever with the first pivoting point as a fulcrum.

Further, the unit base may have a third opening in which the IC socket is housed; and a plurality of side wall portions surrounding the third opening, a bearing base portion may be provided on a first side wall portion which is one of the plurality of side wall portions, and a proximal end side portion of the frame member may be pivotally supported at a fourth pivoting point on the bearing base portion.

Further, a second side wall portion facing the first side wall portion across the third opening therebetween, the second side wall portion provided with a receiving base portion, and at the confronting position, the tip end side portion of the frame member may touch against the receiving base portion, and further rocking may be restricted.

Further, the base of the heat sink may be provided with a first through hole, the heat sink mount may be provided with a second through hole, the frame member may be provided with a screw hole, the heat sink, the heat sink mount, and the frame member may be stacked, and a screw may be screwed into the screw hole through the first through hole and the second through hole.

Further, a second coil spring may be provided inside the heat sink.

Further, a shaft that holds the second coil spring may be included, wherein a fixing hole for passing the shaft may be provided in the frame member or the heat sink mount.

Further, a third coil spring may be provided between the heat sink mount and the frame member.

Further, a coil spring or a torsional coil spring may be provided between the unit base and the frame member to reduce impact when the frame member is closed.

An IC (integrated circuit) socket, which is another preferred aspect of the present invention, is characterized in that the heat sink unit described above is incorporated in a socket main body of the IC socket.

A manufacturing method of semiconductor package, which is another preferred aspect of the present invention, is characterized by including: a semiconductor assembling process of assembling a semiconductor package by applying an external connection terminal, a protective covering, etc., to a semiconductor element; a first sorting process of sorting the semiconductor package in which defects are generated by the semiconductor assembling process; a screening process of discriminating good/defective product by applying thermal load or electrical load to the semiconductor package which is judged to be good through the first sorting process; a second sorting process of sorting the semiconductor package which is judged to be a defective product by the screening process; and a shipping process of shipping the semiconductor package which is judged to be good by the screening process, wherein in the screening process, an IC socket to which the semiconductor package is detachably attached is mounted on a predetermined circuit board, and the heat sink socket according to claim 1 is detachably attached to the IC socket.

A semiconductor package, which is another preferred aspect of the present invention, is manufactured by the manufacturing method described above.

### Effects

The present invention includes: a heat sink having a base and a plurality of radiating fins erected from the base; a unit base mounted on a substrate so as to surround the IC socket; a frame member that has a first opening and supports the heat sink so that a base of the heat sink passes through the first opening, wherein the frame member is supported by the unit base so as to be rockable between a confronting position and an open position tilting with respect to the confronting position, and the confronting position is where an end surface of the base on a side opposite to the radiating fins side and the IC package confront each other at an interval; and a first lever in which an intermediate portion between one end and the other end of the first lever is pivotally supported at a first pivoting point of the frame member, when the frame member reaches the confronting position, further rocking is restricted, the heat sink supported by the frame member vertically moves downward, and the end surface of the heat sink comes into contact with the IC package. Thus, it is possible to provide a heat sink unit 1 that has a small mounting area and high radiating efficiency without breaking or damaging the IC package.

### BRIEF DESCRIPTION OF THE DRAWINGS

FIG. 1A is a perspective view of a heat sink unit 1 according to one embodiment of the present invention in a closed state, and FIG. 1B is a perspective view of the heat sink unit shown in FIG. 1A in an opened state;

FIG. 2 is a perspective view of an IC (integrated circuit) socket 100 used in combination with the heat sink unit 1 shown in FIGS. 1A-1B;

FIG. 3 is a side view of the heat sink unit 1 shown in FIG. 1A as viewed from an +X side;

FIG. 4A-4D is a diagram showing the operation of the heat sink 2 shown in FIGS. 1A-1B;

FIG. 5A is a diagram of the heat sink unit 1 as viewed from obliquely frontward of the heat sink unit 1 immediately before reaching the state shown in FIG. 4B, and

FIG. 5B is a diagram of the heat sink unit 1 in the state shown in FIG. 4C as viewed from obliquely frontward of the heat sink unit 1;

FIG. 6A is a diagram of the inside of the cover 3 of the heat sink 2 in the state shown in FIG. 4B as viewed from a −Y direction, and FIG. 6B is a diagram shown in FIG. 6A as viewed from the +X side;

FIG. 7 is a diagram showing a test device 500 which performs an electrical connection test of an IC socket 100 including an IC (integrated circuit) package;

FIG. 8 is a flow chart showing the flow of a manufacturing method of IC package;

FIG. 9 is a flowchart showing test procedures for testing an IC package.

### DETAILED DESCRIPTION OF THE DRAWINGS

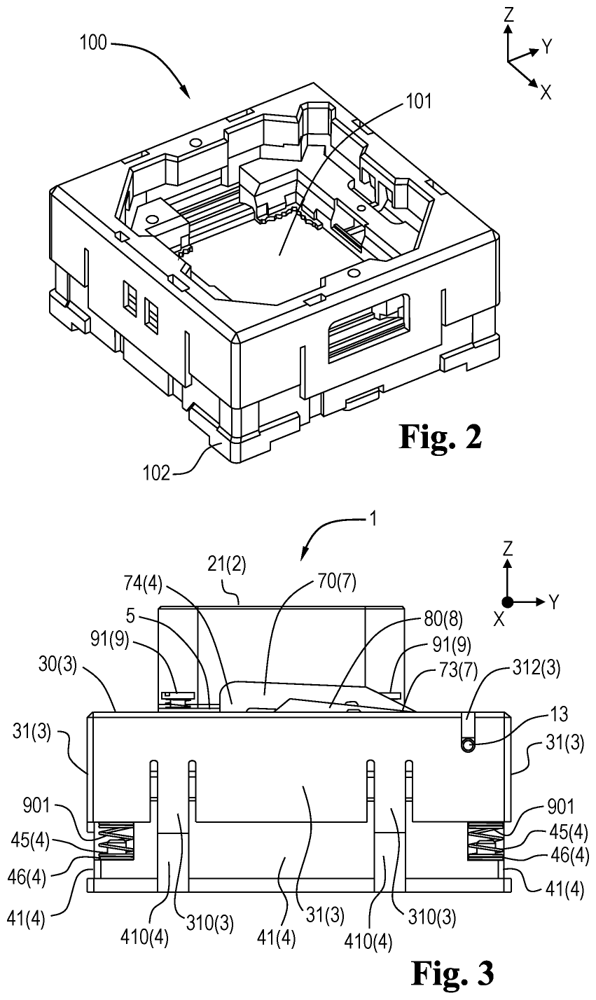

Hereinafter, a heat sink unit 1 according to one embodiment of the present invention is explained with reference to drawings. The heat sink unit 1 dissipates heat of the IC (integrated circuit) package (semiconductor package) accommodated in the IC (integrated circuit) socket 100 during a burn-in test. As shown in FIG. 2, the IC socket 100 has a tray portion 101 and a socket main body 102 surrounding the tray portion 101. In the burn-in test, an IC package to be tested is placed on the tray portion 101, and an electric signal is supplied to the IC package from the substrate on which the IC socket 100 is supported and fixed through the contact pins of the IC socket 100 to perform various evaluations.

In the following description, the direction in which the IC package is accommodated in the IC socket 100 is appropriately referred to as the Z-direction, one direction orthogonal to the Z direction is appropriately referred to as the X direction, and the direction orthogonal to both the Z direction and the X direction is appropriately referred to as the Y direction. In addition, +Z side, which is the open side of the IC socket 100 in the Z direction, may be referred to as the upper side, and the opposite side, the −Z side, may be referred to as the lower side. In addition, the −Y side, which is one side in the Y direction, may be referred to as the front side, and the opposite side, the +Y side, may be referred to as the rear side.

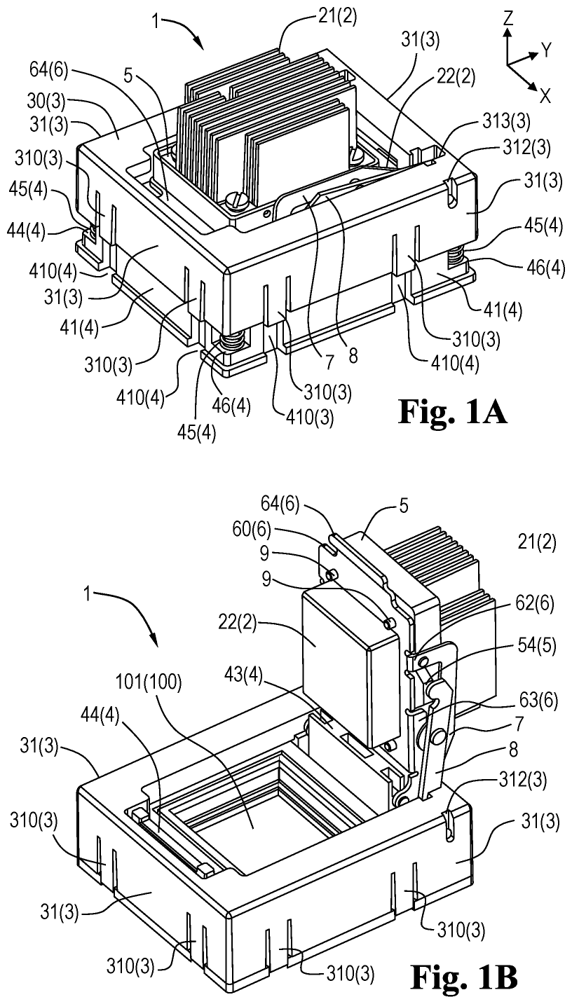

As shown in FIGS. 1A-1B, the heat sink unit 1 comprises a heat sink 2, a cover 3, a unit base 4, a heat sink mount 5, a frame member 6, two first levers 8, and two second levers 7. The configuration of each portion is as follows.

The heat sink 2 has a base 22 and a plurality of radiating fins 21 erected from the base 22. The base 22 is in an approximately rectangular parallelepiped shape. First through holes are perforated at the four corners of the base 22. In this example, the radiating fin 21 is a plate in parallel to the YZ plane. The plurality of radiating fins 21 are arranged at slight intervals in the X direction. It is to be noted that the shape and the arrangement direction of the radiating fins 21 can be arbitrarily changed according to the specifications.

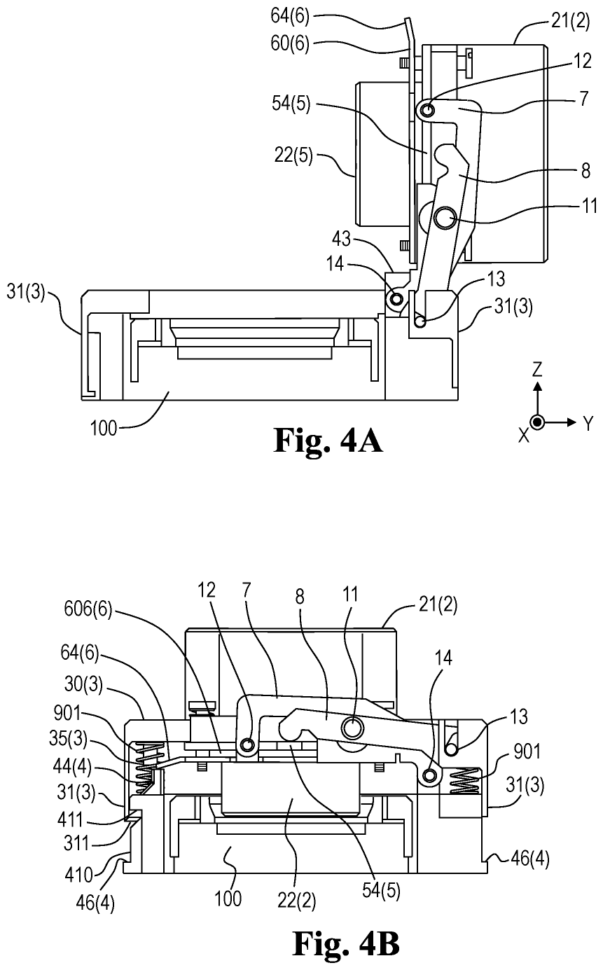

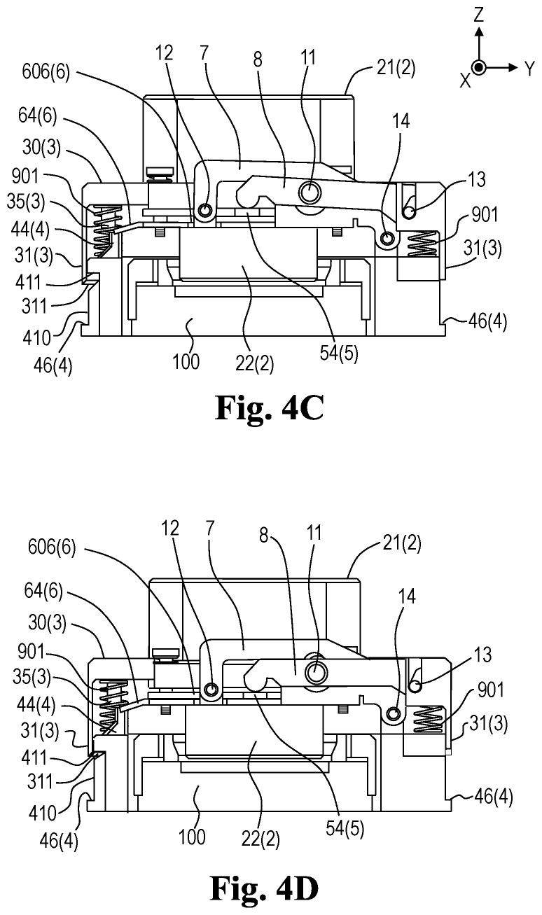

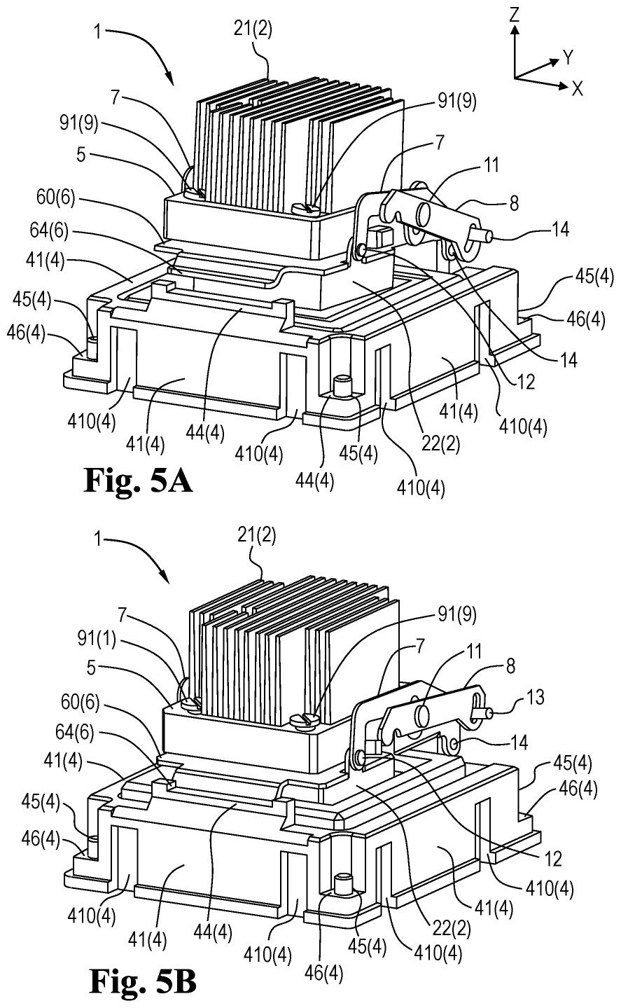

The cover 3 is in a box shape with the −Z side opened. The cover 3 has a top plate and four side plates 31 extending from the four sides of the top plate 30 to the −Z side. Two of the four side plates 31 are opposed to each other in the X direction, and the other two are opposed to each other in the Y direction. A rectangular fourth opening is provided in the center of the top plate 30. As shown in FIGS. 4B-4D, column portions 35 are provided at the four corners of the lower surface of the top plate 30.

A first round hole is bored at a position slightly inward from the corner portion where the side on the +Y side and the side on the +Z side of the side plate 31 facing in the X direction intersect. As shown in FIGS. 1A-1B, grooves 312 and 313 recessed toward the first round hole are provided on the inside and outside of the side plate 31 on the +X side and the side plate 31 on the −X side, respectively.

The side plate 31 of the cover 3 is provided with slits extending from the lower edge to the +Z side and drooping portions 310 across between the slits. As shown in FIGS. 4A-4D, the lower end of the drooping portion 310 is bent inward as a nib portion 311.

The unit base 4 is in an approximately rectangular parallelepiped shape. The unit base 4 has a rectangular third opening in the center and four side wall portions 41 surrounding the third opening. Two of the four side wall portions 41 are opposed to each other in the X direction and the other two side wall portions 41 are opposed to each other in the Y direction. As shown in FIGS. 4A-4D, the thickness of the side wall portion 42 on the +Y side in the Y direction is thicker than the thickness of the side wall portion 42 on the −Y side in the Y direction.

The unit base 4 is mounted on the substrate so that the IC socket 100 is accommodated in the third opening and its four sides are surrounded by the side wall portions 41. The four corners of the unit base 4 are recessed downward as concave portions 46. As shown in FIG. 1A and FIG. 3, a column portion 45 is provided at the bottom of the concave portion 46.

A groove 410 extending from the lower end to the +Z side is provided on the outer surface of the side wall portion 41 of the unit base 4. As shown in FIGS. 4A-4D, the upper edge of the groove 410 in the side wall portion 41 is bent outward as a nib portion 411.

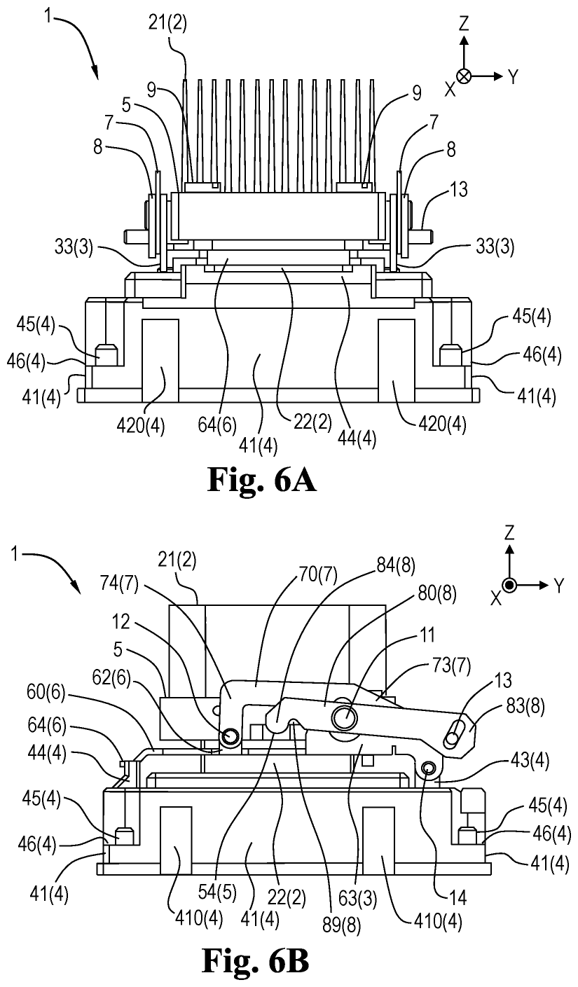

As shown in FIG. 1B and FIG. 6B, a bearing base portion 43 is provided on the third opening side of the upper surface of the side wall portion 41 on the +Y side of the unit base 4. The bearing base portion 43 is provided with a second round hole penetrating the bearing base portion 43 in the X direction. A receiving base portion 44 is provided on the upper surface of the side wall portion 41 on the −Y side of the unit base 4. The two end portions of the receiving base portion 44 in the X direction are raised upward higher than the central portion therebetween.

As shown in FIGS. 4A-4D, the cover 3 and the unit base 4 are combined so that first coil springs 901 are wound around the column portion 35 of the cover 3 and the column portion 45 of the unit base 4, and the nib portions 311 of the drooping portions 310 of the cover 3 are fitted into the grooves 410 of the unit base 4.

The heat sink mount 5 has a dish shape with an approximately the same thickness in the Z direction as that of the top plate 30 of the cover 3. A rectangular second opening is provided in the center of the heat sink mount 5. There are convex portions 54 protruding outward at the centers of the lateral side on the +X side and the lateral side on the −X side of the heat sink mount 5. Second through holes are bored at the four corners of the heat sink mount 5

The frame member 6 has a square frame portion 60, convex portions 62 and 63 vertically bent and extending from two sides of the frame portion 60 facing each other in the X direction, and a convex portion 64 bent and extending from one side that intersects these two sides to the side opposite to the convex portion 62 and the convex portion 63. A rectangular first opening is provided in the center of the frame portion Screw holes, which are fixing holes, are provided at the four corners of the frame portion 60.

The convex portion 62 and the convex portion 63 are separated from each other along the extending direction of the frame portion 60. A third round hole is bored in the convex portion 62. The width of the convex portion 63 is larger than the width of the convex portion 62. A fourth round hole is bored in the convex portion 63.

The end portion of the convex portion 63 on the side far from the convex portion 62 protrudes to the outside of the frame member 6, and this protruding portion extends around the side opposite to the bent side of the convex portion 63. A fifth round hole is bored on the tip end side of the protruding portion of the convex portion 63.

As shown in FIG. 3 and FIG. 6B, the first lever 8 has a linear portion 80 extending in a straight line, a constriction portion 89 on one end side of the linear portion 80, a tip end portion 84 protruding in a semicircular arc-shape to the side orthogonal to the extending direction of the linear portion 80 at the tip of the constriction portion 89, and a proximal end portion 83 bent to the same side as the protruding side of the tip end portion 84 on the other end side of linear portion 80 and extending in wider width. A sixth round hole is bored in the intermediate portion between the tip end portion 84 and the proximal end portion 83 of the linear portion 80. A first slot is bored in the proximal end portion 83.

The second lever 7 has a linear portion 70 extending in a straight line, a bent portion 74 bent in an L-shape and extending at one end of the linear portion 70, and an inclined portion 73 extending obliquely at an obtuse angle on the same side as the bent side of the bent portion 74 at the other end of the linear portion 70. A seventh round hole is bored on the tip end side of the bent portion 74. An eighth round hole is bored on the tip end side of the inclined portion 73. A second slot is bored in the middle of the linear portion 70 between one end and the other end of that.

The heat sink mount 5 supports the heat sink 2, and the frame member 6 supports the heat sink mount 5. The frame member 6 is pivotally supported in the round hole of the bearing base portion 43 of the unit base 4 so as to be rockable between a confronting position (see FIG. 4B) where the end surface of the base 22 of the heat sink 2 on the side opposite to the side of the radiating fin 21 and the IC package confront each other and an open position (see FIG. 4A) tilting at 90 degrees with respect to the confronting position.

More specifically, the heat sink 2, the heat sink mount 5, and the frame member 6 are stacked so that the positions of the first through hole of the heat sink 2, the second through hole of the heat sink mount 5, and the screw hole of the frame member 6 are aligned, and the screw 9 is screwed into the screw hole of the frame member 6 through the through holes of the heat sink 2 and the heat sink mount 5.

A second coil spring (not shown) is provided at a portion around the shaft of the screw 9 between the head 91 of the screw 9 and the base 22 of the heat sink 2, and a third coil spring (not shown) is provided at a portion between the heat sink mount 5 and the frame member 6. The base 22 of the heat sink 2 passes through the second opening of the heat sink mount 5 and the first opening of the frame member 6 and projects to the side opposite to the side of the radiating fin 21.

The frame member 6 is located at a position where the bearing base portion 43 of the unit base 4 is sandwiched from the ±X side by the protruding portions of the convex portions 63 that protrude to the outside of the frame portion 60. The two second levers 7 are located at positions on the outside of the convex portion 63 on the +X side and the convex portion 63 on the −X side in the frame member 6. The two first levers 8 are located at positions on the outside of the two second levers 7 on the +X side and the −X side. The inclined portion 73 of the second lever 7 and the proximal end portion 83 of the first lever 8 are accommodated in the groove 313 of the cover 3.

When viewed from the X direction, the positions of the round hole of the linear portion 80 of the first lever 8, the slot of the proximal end portion 83 of the second lever 7, and the round hole of the erected portion of the convex portion 63 of the frame member are aligned, and the first support shaft 11 is passed through these holes. In addition, the positions of the round hole of the convex portion 62 of the frame member 6 and the round hole of the bent portion 74 of the second lever 7 are aligned, and the second support shaft 12 is passed through these holes. In addition, the positions of the round holes of the side plates 31 on the ±X sides of the cover 3, the slot of the proximal end portion 83 of the first lever 8, and the round hole on the tip end side of the inclined portion 73 of the second lever 7 are aligned, and the third support shaft 13 is passed through these holes. In addition, the positions of the round hole of the protruding portion of the convex portion 63 of the frame member 6 and the round hole of the bearing base portion 43 of the unit base 4 are aligned, and the fourth support shaft 14 is passed through these holes. The distance between the third support shaft 13 and the fourth support shaft 14 is smaller than the distance between the third support shaft 13 and the first support shaft 11.

Here, an urging force in a reverse direction to the Z direction is applied to the cover 3 and the unit base 4 by the first coil spring 901 between the cover 3 and the unit base 4. The first coil spring 901 forms a driving mechanism that produces a force which lifts up portions of the second lever 7 and the first lever 8 where the third support shaft 13 is fitted and pushes the heat sink 2 downward when the frame member 6 is rocked from the open position toward the confronting position.

As shown in FIG. 4A, when the frame member 6 is at the open position, the third support shaft 13 is on the +Y side and the −Z side of the fourth support shaft 14, the second support shaft 12 is on the +Z side of the third support shaft 13, and the first support shaft 11 is on the +Y side of the third support shaft 13 and the second support shaft 12. In addition, the tip end portion 84 of the first lever 8 is separated from the convex portion 54 of the heat sink mount 5. The proximal end portion 83 of the first lever 8 pushes down the cover 3 to a position where the drooping portion 310 thereof contacts the upper surface of the concave portion 46 of the unit base 4, and the elastic restoring force of the first coil spring 901 sandwiched between the cover 3 and the unit base 4 becomes sufficiently large.

When a force is applied from the +Y side to the frame member 6 as well as the heat sink mount 5 and the heat sink 2 supported by the frame member 6, the frame member 6 tilts counterclockwise with the fourth support shaft 14 as a fulcrum, and with this tilting, the second support shaft 12 moves to the −Y side of the first support shaft 11, and the first support shaft 11 moves to the −Y side of the fourth support shaft 14. Further, the first lever 8 rotationally moves counterclockwise with the first support shaft 11 as a fulcrum, and the tip end portion 84 of the first lever 8 approaches the convex portion 54 of the heat sink mount 5. When the first support shaft 11 passes a position directly above the third support shaft 13 by the rotational movement of the first lever 8, the elastic restoring force of the first coil spring 901 is released. Due to the extension of the first coil spring 901, the cover 3 and the proximal end portion 83 of the first lever 8 are raised, and the tip end portion 84 of the first lever 8 is lowered.

As shown in FIG. 4B, when the frame member 6 reaches the confronting position, the tip end portion 84 of the first lever 8 touches against the convex portion 54 of the heat sink mount 5, and the convex portion 64 of the frame member 6 touches against the receiving base portion 44 of the unit base 4. Further tilting of the frame member 6 is restricted by the receiving base portion 44. When the frame member 6 is at the confronting position, the linear portion 70 of the second lever 7 becomes parallel to the frame member 6, and the linear portion 80 of the first lever 8 slightly tilt with respect to the frame member 6. In addition, when the frame member 6 is at the confronting position, the third support shaft 13 is on the +Y side and the +Z side of the fourth support shaft 14, the first support shaft 11 is on the −Y side and the +Z side of the fourth support shaft 14, and the second support shaft 12 is on the −Y side of the first support shaft 11.

As shown in FIG. 4C, after the frame member 6 reaches the confronting position, the proximal end portion 83 of the first lever 8 is lifted by the force of the first coil spring 901, the first lever 8 further rotationally moves with the first support shaft 11 as a fulcrum, and the tip end portion 84 of the first lever 8 pushes down the heat sink mount 5. Then, as shown in FIG. 4D, the linear portion 80 of the first lever 8 becomes parallel to the heat sink mount 5, and the end surface on the lower side of the base 22 of the heat sink 2 contacts the IC package in the IC socket 100.

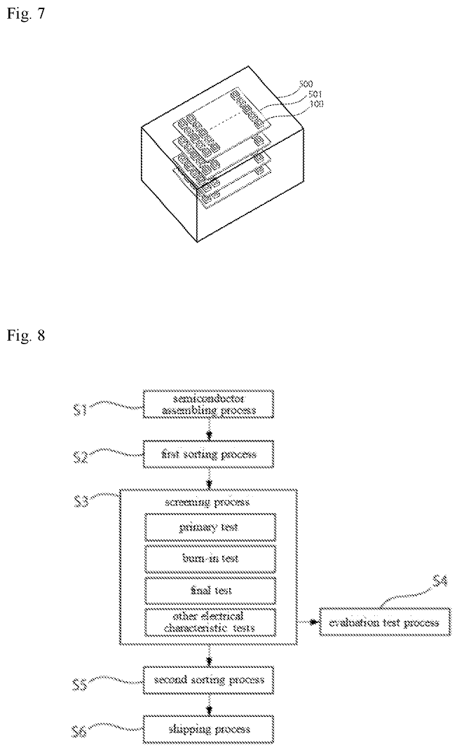

Here, the heat sink unit 1 is incorporated in the socket main body 102 of the IC socket 100 in which the IC package is accommodated. Then, as shown in FIG. 7, a plurality of IC sockets 100 in which the IC package is accommodated are arranged and mounted on a predetermined circuit board 501 of a test device 500, and the test device 500 performs an electrical connection test of the IC package in each IC socket 100.

FIG. 8 is a diagram showing the procedure of a manufacturing method of IC package. The manufacturing method of IC package includes a semiconductor assembling process 51, a first sorting process S2, a screening process S3, an evaluation test process S4, a second sorting process S5, and a shipping process S6. In the semiconductor assembling process 51, an IC package is assembled by applying an external connection terminal, a protective covering, etc., to a semiconductor element. In the first sorting process S2, an IC package in which defects are generated by the semiconductor assembling process 51 is sorted out. In the screening process S3, a good/defective product is discriminated by applying a thermal load or an electrical load to the IC package judged to be good through the first sorting process S2. In the screening process S3, a primary test, a burn-in test, a final test, and other electrical characteristic tests are performed. In addition, the IC socket 100 is attached on the circuit board 501, the IC package is attached to the IC socket 100, and the heat sink unit 1 is attached to the IC package. In the shipping process S6, the IC package judged to be good by the screening process S3 is shipped.

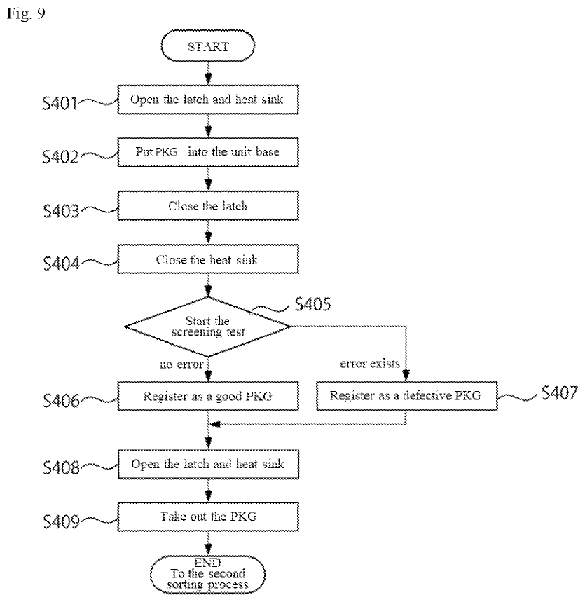

FIG. 9 is a flowchart showing the procedure of the evaluation test process S4. In step S401 of FIG. 9, the latch and the heat sink 2 are opened. In the next step S402, the IC package is put into the unit base 4. In the next step S403, the latch is closed. In the next step S404, the heat sink 2 is closed.

In the next step S405, the screening test is started. If there is no error in this test, the process proceeds to step S406; if there is an error, the process proceeds to step S407. In step S406, it is registered as a good package. In step S407, it is registered as a defective package. After that, the process proceeds to step S408.

In step S408, the latch and the heat sink 2 are opened. In the next step S409, the IC package is taken out. All the processing is completed by the above, and it proceeds to the second sorting process S5.

The above is the details of the present embodiment. The heat sink unit 1 of the present embodiment comprises: a heat sink 2 having a base 22 and a plurality of radiating fins erected from the base 22; a unit base 4 mounted on a substrate so as to surround the IC socket 100; a frame member 6 that has a first opening and supports the heat sink 2 so that the base of the heat sink 2 passes through the first opening, wherein the frame member 6 is supported by the unit base 4 so as to be rockable between a confronting position and an open position tilting with respect to the confronting position, and the confronting position is where the end surface of the base 22 on the side opposite to the radiating fins 21 side and the IC package confront each other at an interval; a first lever 8 in which an intermediate portion between one end and the other end of the first lever 8 is pivotally supported in a round hole of the erected portion of the convex portion 63, which is the first pivoting point of the frame member 6; and a second lever 7 in which an intermediate portion between one end and the other end of the second lever 7 is pivotally supported in a round hole of the erected portion of the convex portion 63, which is the first pivoting point of the frame member 6, and one end side portion of the second lever 7 is pivotally supported in a round hole of the convex portion 62, which is the second pivoting point away from the first pivoting point in the frame member 6. Then, when the frame member 6 reaches the confronting position, further rocking is restricted, the heat sink 2 supported by the frame member 6 moves downward, and the end surface of the heat sink 2 comes into contact with the IC package. Thus, it is possible to provide a heat sink unit 1 that has a small mounting area and high radiating efficiency.

Further, in the present embodiment, a second coil spring is provided between the head 91 of the screw 9 and the base 22 of the heat sink 2. Thus, it is possible to reduce the impact when the convex portion 64 of the frame member 6 hits the receiving base portion 44 of the unit base 4.

Further, in the present embodiment, a third coil spring is provided between the heat sink mount 5 and the frame member 6. Thus, the heat sink mount 5 and the heat sink 2 become in a floating state with respect to the frame member 6 until the frame member 6 reaches the confronting position. Thus, it is possible to avoid a situation in which the heat sink mount 5 and the heat sink 2 sink and the heat sink 2 touches the package IC before the frame member 6 reaches the confronting position.

Although the embodiment of the present disclosure has been described above, the following modifications may be added to this embodiment.

(1) In the above embodiment, the first lever 8 and the second lever 7 were arranged one each on the +X side and the −X side of the frame member 6 so as to sandwich the frame member 6 from the +X side and the −X side. However, the first lever 8 and the second lever 7 may be arranged one each on either the +X side or the −X side of the frame member 6.

(2) In the above embodiment, the first lever 8 was arranged on the outside of the frame member 6, and the second lever 7 was arranged on the outside thereof. However, the arrangement of the first lever 8 and the second lever 7 between the frame member 6 and the side plate 31 of the cover 3 may be reversed, the second lever 7 may be arranged on the outside of the frame member 6, and the first lever 8 may be arranged on the outside thereof.

(3) In the above embodiment, the screw hole of the frame member 6 may be replaced with a normal through hole. The heat sink 2, the heat sink mount 5, and the frame member 6 may be integrated by fitting of bolts and nuts.

(4) In the above embodiment, by providing a screw groove in the first through hole of the heat sink 2 and the second through hole of the heat sink mount 5, these holes may be used as fixing holes for fixing the shaft.

(5) In the above embodiment, a coil spring or a torsional coil spring may be provided between the unit base 4 and the frame member 6 to reduce the impact when the frame member 6 is closed.

(6) In the above embodiment, the heat sink mount 5 may be supported by the support portion of the second lever 7.

1. A heat sink unit that dissipates heat of an IC (integrated circuit) package accommodated in an IC (integrated circuit) socket, comprising:
a heat sink having a base and a plurality of radiating fins erected from the base;
a unit base mounted on a substrate so as to surround the IC socket;
a frame member that has a first opening and supports the heat sink so that a base of the heat sink passes through the first opening, wherein the frame member is supported by the unit base so as to be rockable between a confronting position and an open position tilting with respect to the confronting position, and the confronting position is where an end surface of the base on a side opposite to the radiating fins side and the IC package confront each other at an interval; and
a first lever in which an intermediate portion between one end and the other end of the first lever is pivotally supported at a first pivoting point of the frame member, when the frame member reaches the confronting position, further rocking is restricted, the heat sink supported by the frame member moves downward, and the end surface of the heat sink comes into contact with the IC package.

2. The heat sink unit according to claim 1, comprising a heat sink mount that has a second opening and supports the heat sink so that the base of the heat sink passes through the second opening, wherein the frame member supports the heat sink and the heat sink mount.

3. The heat sink unit according to claim 2, wherein when the frame member reaches the confronting position, further rocking is restricted, and the heat sink mount and the heat sink supported thereon move downward.

4. The heat sink unit according to claim 3, wherein one end side portion of the first lever is in contact with and separated from the heat sink mount.

5. The heat sink unit according to claim 4, comprising a second lever in which an intermediate portion between one end and the other end of the second lever is pivotally supported at the first pivoting point on the frame member, and one end side portion of the second lever is pivotally supported at a second pivoting point on the frame member that is separated from the first pivoting point.

6. The heat sink unit according to claim 5, comprising a driving mechanism in which a force is generated to lift upward the other end side portion of the second lever and the other end side portion of the first lever when the frame member is rocked from the open position toward the confronting position.

7. The heat sink unit according to claim 6, comprising:
a cover combined with the unit base; and
a first coil spring that is sandwiched between the unit base and the cover to form the driving mechanism, wherein a proximal end side portion of the second lever and a proximal end side portion of the first lever are pivotally supported at a third pivoting point on the side plate of the cover.

8. The heat sink unit according to claim 7, wherein when the frame member is at the open position, the proximal end side portion of the first lever pushes down the cover, and an elastic restoring force of the first coil spring is released when the first pivoting point passes a position directly above the third pivoting point by rotational movement of the first lever with the first pivoting point as a fulcrum.

9. The heat sink unit according to claim 8, wherein the unit base has a third opening in which the IC socket is accommodated; and a plurality of side wall portions surrounding the third opening,
a bearing base portion is provided on a first side wall portion which is one of the pluralities of the side wall portions, and
a proximal end side portion of the frame member is pivotally supported at a fourth pivoting point on the bearing base portion.

10. The heat sink unit according to claim 9, wherein a second side wall portion facing the first side wall portion across the third opening therebetween, the second side wall portion provided with a receiving base portion, and at the confronting position, the tip end side portion of the frame member touches against the receiving base portion, and further rocking is restricted.

11. The heat sink unit according to claim 10, wherein the base of the heat sink is provided with a first through hole,
the heat sink mount is provided with a second through hole,
the frame member is provided with a fixing hole,
the heat sink, the heat sink mount, and the frame member are stacked, and a screw is screwed into the fixing hole through the first through hole and the second through hole.

12. The heat sink unit according to claim 11, wherein a second coil spring is provided inside the heat sink.

13. The heat sink unit according to claim 12, comprising a shaft that holds the second coil spring, wherein a fixing hole for passing the shaft is provided in the frame member or the heat sink mount.

14. The heat sink unit according to claim 13, wherein a third coil spring is provided between the heat sink mount and the frame member.

15. The heat sink unit according to claim 14, wherein a coil spring or a torsional coil spring is provided between the unit base and the frame member to reduce impact when the frame member is closed.

16. The heat sink unit according to claim 6, wherein the heat sink mount is supported by a support portion of the second lever.

17. An IC (integrated circuit) socket, wherein a heat sink unit according to claim 1 is incorporated in a socket main body of the IC socket.

18. A manufacturing method of semiconductor package, comprising:
a semiconductor assembling process of assembling a semiconductor package by applying an external connection terminal, a protective covering, etc., to a semiconductor element;
a first sorting process of sorting out the semiconductor package in which defects are generated by the semiconductor assembling process;
a screening process of discriminating a product quality by applying thermal load or electrical load to the semiconductor package judged to be good through the first sorting process;
a second sorting process of sorting the semiconductor package which is judged to be defective by the screening process; and
a shipping process of shipping the semiconductor package which is judged to be good by the screening process,
wherein during the screening process, an IC socket to which the semiconductor package is detachably attached is mounted on a predetermined circuit board, and the heat sink socket according to claim 1 is detachably attached to the IC socket.

19. A semiconductor package manufactured by the manufacturing method of semiconductor package according to claim 18.
